(19) United States
(12) Patent Application Publication
(10) Pub. No.: US 2026/0090165 A1
(43) Pub. Date: Mar. 26, 2026

(54) DISPLAY DEVICE INCLUDING LIGHT EMITTING DIODE

(71) Applicant: LG Display Co., Ltd., Seoul (KR)

(72) Inventors: Hyeong-Seok KIM, Paju-si (KR); Min-Seok KIM, Paju-si (KR); Rok-Hee LEE, Paju-si (KR); Moon-Bae GEE, Paju-si (KR)

(73) Assignee: LG Display Co., Ltd., Seoul (KR)

(21) Appl. No.: 19/193,685

(22) Filed: Apr. 29, 2025

(30) Foreign Application Priority Data
Sep. 23, 2024 (KR) 10-2024-0128480

(51) Int. Cl. H10H 29/34; H10H 29/39

(52) U.S. Cl. CPC H10H 29/345; H10H 29/39

(57) ABSTRACT

A display device includes: a display panel having a display area and a non-display area at a periphery of the display area; a plurality of gate lines and a plurality of data lines in the display area, the plurality of gate lines and the plurality of data lines crossing each other to define first, second and third subpixels; a driving transistor in each of the first, second and third subpixels and connected to the plurality of gate lines and the plurality of data lines; and first, second and third light emitting diodes in the first, second and third subpixels, respectively, and connected to the driving transistor, one corner of the first light emitting diode, one corner of the second light emitting diode and one corner of the third light emitting diode having asymmetric angled shapes different from each other.

### CROSS-REFERENCE TO RELATED APPLICATION

The present application claims the priority of Republic of Korea Patent Application No. 10-2024-0128480 filed on Sep. 23, 2024, which is hereby incorporated by reference in its entirety.

### BACKGROUND

### Technical Field

The present disclosure relates to a display device, and more particularly, to a display device including a light emitting diode having an asymmetric angled shape.

### Description of the Related Art

Recently, various flat panel display devices such as a liquid crystal display device (LCD), an organic light emitting diode (OLED) display device and a field emission display (FED) device having excellent properties of a thin profile, a light weight and a low power consumption have been developed and applied to various fields.

Although the OLED display device among the various flat panel display devices has an advantage such that an additional light source is not required, the OLED display device has a disadvantage such that deterioration may occur by an external circumstance due to a property of an organic material vulnerable to a moisture and an oxygen.

To overcome the disadvantage, a display device using a light emitting diode chip (or a light emitting diode) of an inorganic material has been suggested.

The light emitting diode chip is attached to a display panel after the light emitting diode chip is formed on a growth substrate. To distinguish red, green and blue light emitting diode chips from each other, the red, green and blue light emitting diode chips are formed to have elliptical shapes having different long axes and different short axes.

### BRIEF SUMMARY

The inventors of the present disclosure have recognized that as display resolution increases, the size of light-emitting diode (LED) chips decreases. As a result, an exclusivity according to a long axis and a short axis of the light emitting diode chip may be reduced, and the light emitting diode may be broken. Accordingly, the present disclosure is directed to various embodiments of a display device that substantially obviates one or more of the problems due to limitations and disadvantages of the related art, including the above-identified problem.

More specifically, the present disclosure is to provide a display device including a light emitting diode where a color mixture is prevented and a fabrication process is optimized by forming the light emitting diode as an asymmetric angled shape.

Further, the present disclosure is to provide a display device including a light emitting diode applicable to a high resolution by forming red, green and blue light emitting diodes as different asymmetric angled shapes and a method of fabricating the display device.

Additional embodiments include a method of fabricating a display device. The method includes forming red, green, and blue LEDs with different asymmetric angled shapes. The method includes forming corresponding assembly grooves. The method includes assembling the LEDs into the grooves using a force.

In some embodiments, the force includes one or more of a dielectric phoretic force, an electric force, or a magnetic force. For example, it may be a single force or a combination of these forces.

In some embodiments, assembling the LEDs into the grooves using a force includes a self-correcting mechanism in which an incorrectly aligned LED is dislodged by the force.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a display panel having a display area and a non-display area at a periphery of the display area; a plurality of gate lines and a plurality of data lines in the display area, the plurality of gate lines and the plurality of data lines crossing each other to define first, second and third subpixels; a driving transistor in each of the first, second and third subpixels and connected to the plurality of gate lines and the plurality of data lines; and first, second and third light emitting diodes in the first, second and third subpixels, respectively, and connected to the driving transistor, one corner of the first light emitting diode, one corner of the second light emitting diode and one corner of the third light emitting diode having asymmetric angled shapes different from each other.

It is to be understood that both the foregoing general description and the following detailed description are explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure.

In the drawings:

FIG. 1 is a view showing a display device according to a first embodiment of the present disclosure;

FIG. 2 is a circuit diagram showing a subpixel of a display device according to a first embodiment of the present disclosure;

FIG. 3 is a cross-sectional view showing a subpixel of a display panel of a display device according to a first embodiment of the present disclosure;

FIG. 4 is a view showing an assembly substrate of a light emitting diode of a display device according to a first embodiment of the present disclosure;

FIG. 5 is a magnified view of a portion A of FIG. 4;

FIG. 6A is a view showing a first assembly groove of an assembly substrate and a first light emitting diode for a fabrication of a display device according to a first embodiment of the present disclosure;

FIG. 6B is a view showing a first assembly groove of an assembly substrate and a second light emitting diode for a fabrication of a display device according to a first embodiment of the present disclosure;

FIG. 6C is a view showing a first assembly groove of an assembly substrate and a third light emitting diode for a fabrication of a display device according to a first embodiment of the present disclosure;

FIG. 7A is a view showing a second assembly groove of an assembly substrate and a second light emitting diode for a fabrication of a display device according to a first embodiment of the present disclosure;

FIG. 7B is a view showing a second assembly groove of an assembly substrate and a first light emitting diode for a fabrication of a display device according to a first embodiment of the present disclosure;

FIG. 7C is a view showing a second assembly groove of an assembly substrate and a third light emitting diode for a fabrication of a display device according to a first embodiment of the present disclosure;

FIG. 8A is a view showing a third assembly groove of an assembly substrate and a third light emitting diode for a fabrication of a display device according to a first embodiment of the present disclosure;

FIG. 8B is a view showing a third assembly groove of an assembly substrate and a first light emitting diode for a fabrication of a display device according to a first embodiment of the present disclosure;

FIG. 8C is a view showing a third assembly groove of an assembly substrate and a second light emitting diode for a fabrication of a display device according to a first embodiment of the present disclosure;

FIG. 9 is a view showing a first assembly groove of an assembly substrate and a first light emitting diode for a fabrication of a display device according to a second embodiment of the present disclosure;

FIG. 10 is a view showing a first assembly groove of an assembly substrate and a first light emitting diode for a fabrication of a display device according to a third embodiment of the present disclosure;

FIG. 11 is a view showing second and third assembly grooves of an assembly substrate and second and third light emitting diodes for a fabrication of a display device according to a fourth embodiment of the present disclosure;

FIG. 12 is a view showing second and third assembly grooves of an assembly substrate and second and third light emitting diodes for a fabrication of a display device according to a fifth embodiment of the present disclosure; and

FIG. 13 is a view showing second and third assembly grooves of an assembly substrate and second and third light emitting diodes for a fabrication of a display device according to a sixth embodiment of the present disclosure.

### DETAILED DESCRIPTION

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure may be sufficiently thorough and complete to assist those skilled in the art to fully understand the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

As used herein, the terms “connected” and “coupled” are intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” should be interpreted in the same manner.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device,” and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or oxygen into the emitting element layer. In addition, the emitting element layer on the array may include an inorganic light emitting layer, for example, a nano-sized material layer or a quantum dot.

The thin film transistor of the present disclosure may include one of an oxide thin film transistor, an amorphous silicon thin film transistor, and a low temperature polycrystalline silicon thin film transistor.

Features of various embodiments of the present disclosure may be partially or entirely coupled to or combined with each other. They may be linked and operated technically in various ways as those skilled in the art may sufficiently understand. The aspects may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

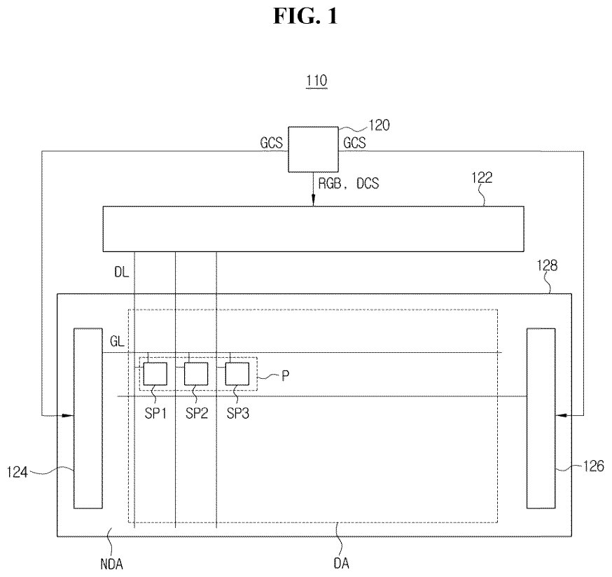

FIG. 1 is a view showing a display device according to a first embodiment of the present disclosure. Although the display device may be an organic light emitting diode (OLED) display device, it is not limited thereto. For example, the display device may be a micro light emitting diode (LED) display device or a mini light emitting diode (LED) display device.

In FIG. 1, a display device 110 according to a first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS and a gate control signal GCS using an image signal and a plurality of timing signals including a data enable signal, a horizontal synchronization signal, a vertical synchronization signal and a clock signal transmitted from an external system such as a graphic card or a television system. The timing controlling unit 120 transmits the image data RGB and the data control signal DCS to the data driving unit 122, and transmits the gate control signal GCS to the first and second gate driving units 124 and 126.

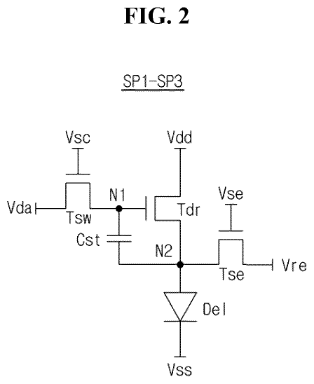

The data driving unit 122 generates a data signal (a data voltage) Vda (of FIG. 2) using the image data RGB and the data control signal DCS transmitted from the timing controlling unit 120 and transmits the data signal Vda to a data line DL of the display panel 128.

The first and second gate driving units 124 and 126 generate a gate signal (a gate voltage) Vsc and Vse (of FIG. 2) using the gate control signal GCS transmitted from the timing controlling unit 120 and applies the gate signal Vsc and Vse to a gate line GL of the display panel 128.

The first and second gate driving units 124 and 126 may have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit may be disposed in one side portion of the display panel 128 in another embodiment.

The display panel 128 includes a display area DA at a central portion thereof and a non-display area NDA surrounding the display area DA. The display panel 128 displays an image using the gate signal Vsc and Vse and the data signal Vda. For displaying an image, the display panel 128 includes a plurality of pixels P, a plurality of gate lines GL and a plurality of data lines DL in the display area DA.

Each of the plurality of pixels P includes first, second and third subpixels SP1, SP2 and SP3, and the gate line GL and the data line DL cross each other to define the first, second and third subpixels SP1, SP2 and SP3. Each of the first, second and third subpixels SP1, SP2 and SP3 is connected to the gate line GL and the data line DL. For example, the first, second and third subpixels SP1, SP2 and SP3 may correspond to first, second and third colors, respectively, and the first, second and third colors may be red, green and blue colors, respectively.

Each of the first, second and third subpixels SP1, SP2 and SP3 may include a plurality of transistors such as a switching transistor Tsw (of FIG. 2), a driving transistor Tdr (of FIG. 2) and a sensing transistor Tse (of FIG. 2), a storage capacitor Cst (of FIG. 2) and a light emitting diode Del (of FIG. 2).

FIG. 2 is a circuit diagram showing a subpixel of a display device according to a first embodiment of the present disclosure.

In FIG. 2, each of the first, second and third subpixels SP1, SP2 and SP3 of the display panel 128 of the display device 110 according to a first embodiment of the present disclosure includes a switching transistor Tsw, a driving transistor Tdr, a sensing transistor Tse, a storage capacitor Cst and a light emitting diode Del.

Although each of the first, second and third subpixels SP1, SP2 and SP3 has a 3T1C structure having three transistors and one storage capacitor in the first embodiment of FIG. 2, each of the first, second and third subpixels SP1, SP2 and SP3 may have one of a 6T1C structure having six transistors and one storage capacitor, a 7T1C structure having seven transistors and one storage capacitor and a 8T1C structure having eight transistors and one storage capacitor in another embodiment.

Although the switching transistor Tsw, the driving transistor Tdr and the sensing transistor Tse may have a negative type in the first embodiment of FIG. 2, at least one of the switching transistor Tsw, the driving transistor Tdr and the sensing transistor Tse may have a positive type in another embodiment.

The switching transistor Tsw is switched according to a scan signal Vsc to transmit a data signal Vda to a first node N1.

A gate electrode of the switching transistor Tsw is connected to the gate line GL to receive the scan signal Vsc, a drain electrode of the switching transistor Tsw is connected to the data line DL to receive the data signal Vda, and a source electrode of the switching transistor Tsw is connected to the first node N1.

The driving transistor Tdr is switched according to a voltage of the first node N1 to transmit a high level signal (high level voltage) Vdd to a second node N2.

A gate electrode of the driving transistor Tdr is connected to the first node N1, a drain electrode of the driving transistor Tdr is connected to a high level power line to receive the high level signal Vdd, and a source electrode of the driving transistor Tdr is connected to the second node N2.

The sensing transistor Tse is switched according to a sensing signal (sensing voltage) Vse to transmit a reference signal (reference voltage) Vre to the second node N2 or transmit a voltage of the second node N3 to a reference line.

A gate electrode of the sensing transistor Tse is connected to the gate line GL to receive the sensing signal Vse, a drain electrode of the sensing transistor Tse is connected to the reference line to receive the reference signal Vre or transmit a voltage of the second node N2 to the reference line, and a source electrode of the sensing transistor Tse is connected to the second node N2.

The storage capacitor Cst keeps the data signal Vdata supplied to the first node N1 for one frame and stores a threshold voltage Vth of the driving transistor Tdr.

A first capacitor electrode of the storage capacitor Cst is connected to the first node N1, and a second capacitor electrode of the storage capacitor Cst is connected to the second node N2.

The light emitting diode Del emits a light of a luminance proportional to a current of the driving transistor Tdr.

An anode of the light emitting diode Del is connected to the second node N2, and a cathode of the light emitting diode Del is connected to a low level power line to receive a low level signal (low level voltage) Vss.

The source electrode of the switching transistor Tsw, the gate electrode of the driving transistor Tdr and the first capacitor electrode of the storage capacitor Cst constitute the first node N1, and the source electrode of the driving transistor Tdr, the source electrode of the sensing transistor Tse, the second capacitor electrode of the storage capacitor Cst and anode of the light emitting diode Del constitute the second node N2.

The light emitting diode Del may display an image having a luminance corresponding to the image data RGB according to a driving of subpixel circuits of the first, second and third subpixels SP1, SP2 and SP3.

A cross-sectional structure of each subpixel SP1, SP2 and SP3 of the display panel 128 of the display device 110 will be illustrated with reference to a drawing.

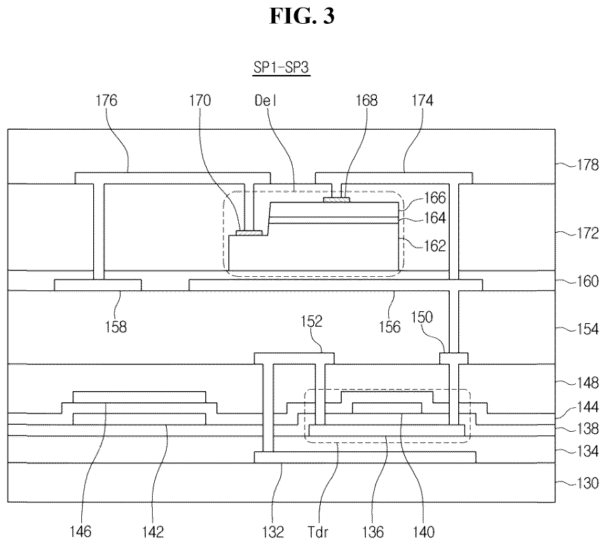

FIG. 3 is a cross-sectional view showing a subpixel of a display panel of a display device according to a first embodiment of the present disclosure.

In FIG. 3, a light shielding pattern 132 is disposed in each of the first, second and third subpixels SP1, SP2 and SP3 on a substrate 130, and a first buffer layer 134 is disposed on the light shielding pattern 132 over the entire substrate 130.

The light shielding pattern 132 may block a light incident from a lower portion of the substrate 130. For example, the light shielding pattern 132 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

The first buffer layer 134 may block a moisture or an oxygen permeating from an exterior. For example, the first buffer layer 134 may have a single layer or a multiple layer of an inorganic insulating material such as silicon oxide (SiO2) and silicon nitride (SiNx).

A semiconductor layer 136 is disposed on the first buffer layer 134 corresponding to the light shielding pattern 132, and a gate insulating layer 138 is disposed on the semiconductor layer 136 over the entire substrate 130.

The semiconductor layer 136 includes a channel region not doped with an impurity at a central portion thereof and source and drain regions doped with an impurity at both side portions of the channel region. For example, the semiconductor layer 136 may include a polycrystalline semiconductor material such as polycrystalline silicon or an oxide semiconductor material such as indium gallium zinc oxide (IGZO), zinc oxide (ZnO), tin oxide (SnO2), copper oxide (Cu2O), nickel oxide (NiO), indium tin zinc oxide (ITZO) and indium aluminum zinc oxide (IAZO).

For example, the gate insulating layer 138 may have a single layer or a multiple layer of an inorganic insulating material such as silicon oxide (SiO2) and silicon nitride (SiNx).

A gate electrode 140 is disposed on the gate insulating layer 138 corresponding to the channel region of the semiconductor layer 136, a first capacitor electrode 142 separated from the gate electrode 140 is disposed on the gate insulating layer 138, and the a first interlayer insulating layer 144 is disposed on the gate electrode 140 and the first capacitor electrode 142.

The gate electrode 140 and the first capacitor electrode 142 may have the same layer and the same material as each other. For example, the gate electrode 140 and the first capacitor electrode 142 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first interlayer insulating layer 144 may have a single layer or a multiple layer of an inorganic insulating material such as silicon oxide (SiO2) and silicon nitride (SiNx).

A second capacitor electrode 146 is disposed on the first interlayer insulating layer 144 corresponding to the first capacitor electrode 142, and a second interlayer insulating layer 148 is disposed on the second capacitor electrode 146 over the entire substrate 130.

For example, the second capacitor electrode 146 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the second interlayer insulating layer 148 may have a single layer or a multiple layer of an inorganic insulating material such as silicon oxide (SiO2) and silicon nitride (SiNx).

The first capacitor electrode 142, the first interlayer insulating layer 144 and the second capacitor electrode 146 may constitute the storage capacitor Cst.

A source electrode 150 and a drain electrode 152 spaced apart from each other are disposed on the second interlayer insulating layer 148, and a first planarizing layer 154 is disposed on the source electrode 150 and the drain electrode 152 over the entire substrate 130.

The source electrode 150 and the drain electrode 152 are connected to the source region and the drain region, respectively, of the semiconductor layer 136 through contact holes in the second interlayer insulating layer 148, the first interlayer insulating layer 144 and the gate insulating layer 138, and the drain electrode 152 is connected to the light shielding pattern 132 through a contact hole in the second interlayer insulating layer 148, the first interlayer insulating layer 144, the gate insulating layer 138 and the first buffer layer 134.

The source electrode 150 and the drain electrode 152 may have the same layer and the same material as each other. For example, the source electrode 150 and the drain electrode 152 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the first planarizing layer 154 may have a single layer or a multiple layer of an organic insulating material such as photoacryl and benzocyclobutene (BCB).

The semiconductor layer 136, the gate electrode 140, the source electrode 150 and the drain electrode 152 may constitute the driving transistor Tdr.

A connecting electrode 156 is disposed on the first planarizing layer 154 corresponding to the source electrode 150, a power line 158 spaced apart from the connecting electrode 156 is disposed on the first planarizing layer 154, and an adhesive layer 160 is disposed on the connecting electrode 156 and the power line 158 over the entire substrate 130.

The connecting electrode 156 is connected to the source electrode 150 through a contact hole in the first planarizing layer 154, and the connecting electrode 156 and the power line 158 may have the same layer and the same material as each other.

For example, the connecting electrode 156 and the power line 158 may have a single layer or a multiple layer of a metallic material such as one of molybdenum (Mo), aluminum (Al), chromium (Cr), gold (Au), titanium (Ti), nickel (Ni), neodymium (Nd), copper (Cu) and an alloy thereof.

For example, the power line 158 may supply the low level signal Vss.

A first semiconductor layer 162 is disposed on the adhesive layer 160 corresponding to the connecting electrode 156, an active layer 164, a second semiconductor layer 166 and a first electrode 168 are sequentially disposed on a first side portion of the first semiconductor layer 162, and a second electrode 170 is disposed on a second side portion of the first semiconductor layer 162.

The first semiconductor layer 162 supplies an electron to the active layer 164, the second semiconductor layer 166 supplies a hole to the active layer 164, and the active layer 164 generates a light using an electron and a hole.

For example, the first semiconductor layer 162 may include a negative type gallium nitride (n-GaN), the second semiconductor layer 166 may include a positive type gallium nitride (p-GaN), and the active layer 164 may include a multi quantum well (MQW).

For example, the first electrode 168 may be an anode, and the second electrode 170 may be a cathode.

The first semiconductor layer 162, the active layer 164, the second semiconductor layer 166, the first electrode 168 and the second electrode 170 may constitute the light emitting diode Del (or light emitting diode chip).

A second planarizing layer 172 is disposed on the first and second electrodes 168 and 170 over the entire substrate 130, and first and second connecting lines 174 and 176 spaced apart from each other are disposed on the second planarizing layer 172 corresponding to the light emitting diode Del.

For example, the second planarizing layer 172 may have a single layer or a multiple layer of an organic insulating material such as photoacryl and benzocyclobutene (BCB).

The first connecting line 174 is connected to the connecting electrode 156 through a contact hole in the adhesive layer 160 and the second planarizing layer 172 and connected to the first electrode 168 through a contact hole in the second planarizing layer 172.

The second connecting line 176 is connected to the power line 158 through a contact hole in the adhesive layer 160 and the second planarizing layer 172 and connected to the second electrode 170 through a contact hole in the second planarizing layer 172.

For example, the first and second connecting lines 174 and 176 may include a transparent conductive material such as indium tin oxide (ITO) and indium zinc oxide (IZO).

An encapsulating layer 178 is disposed on the first and second connecting lines 174 and 176 over the entire substrate 130.

The encapsulating layer 178 prevents a permeation of a particle such as an oxygen or a moisture.

For example, the encapsulating layer 178 may have a single layer or a multiple layer of an inorganic insulating material such as silicon oxide (SiO2) and silicon nitride (SiNx).

Although the light emitting diode Del exemplarily has a horizontal type in the first embodiment, the light emitting diode Del may have a vertical type in another embodiment.

The light emitting diode Del of the display device 110 may be attached to the substrate 130 through a self-assembly technology.

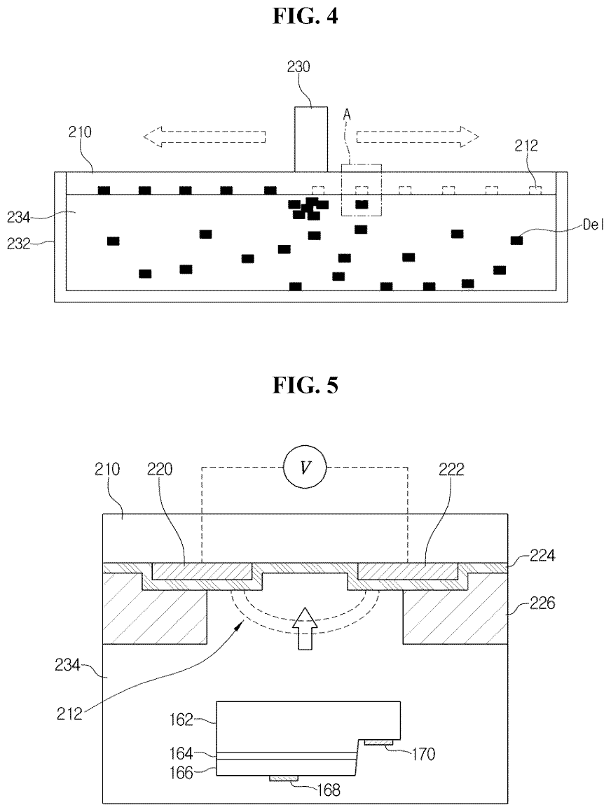

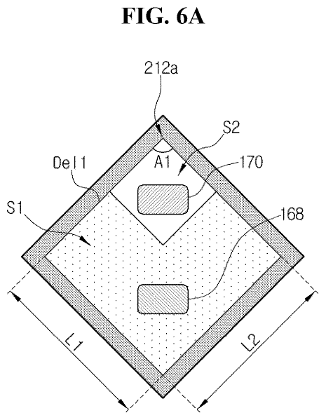

FIG. 4 is a view showing an assembly substrate of a light emitting diode of a display device according to a first embodiment of the present disclosure, and FIG. 5 is a magnified view of a portion A of FIG. 4.

In FIG. 4, an assembly substrate 210 having a plurality of assembly grooves 212 is disposed over a chamber 232, a magnetic rod 230 generating a magnetic field is disposed over the assembly substrate 210, and a fluid 234 including a plurality of light emitting diodes (LEDs) Del is disposed in the chamber 232.

The magnetic rod 230 may move along up, down, left and right directions and rotate, and the plurality of LEDs Del may be formed on a growth substrate and then be detached from the growth substrate.

For example, the fluid 234 may include a water such as a deionized water.

The plurality of LEDs Del moves toward the assembly substrate 210 in the fluid 234 by the magnetic field of the magnetic rod 230, and the LED Del may have a magnetic layer.

For example, the magnetic layer may include a metal having a magnetic property such as nickel (Ni) and may be disposed in one of first and second electrodes 168 and 170 of the LED Del.

In FIG. 5, first and second assembly electrodes 220 and 222 spaced apart from each other are disposed on a lower surface of the assembly substrate 210, and an insulating layer 224 is disposed on the first and second assembly electrodes 220 and 222 over the entire assembly substrate 210.

For example, the first and second assembly electrodes 220 and 222 may include a transparent conductive material or a metallic material, and the insulating layer 224 may have a single layer or a multiple layer of an inorganic insulating material or an organic insulating material.

Sidewalls 226 are disposed on the insulating layer 224 corresponding to the first and second assembly electrodes 220 and 222. The sidewalls 226 partially overlap the first and second assembly electrodes 220 and 222, and a space between the sidewalls 226 constitutes the assembly groove 212.

When an alternating current (AC) voltage is applied to the first and second assembly electrodes 220 and 222, an electric field is generated between the first and second assembly electrodes 220 and 222, and the LED Del adjacent to the plurality of assembly grooves 212 among the plurality of LEDs Del in the fluid 234 may be assembled to the assembly groove 212 by a dielectric phoretic force due to the electric field generated between the first and second assembly electrodes 220 and 222.

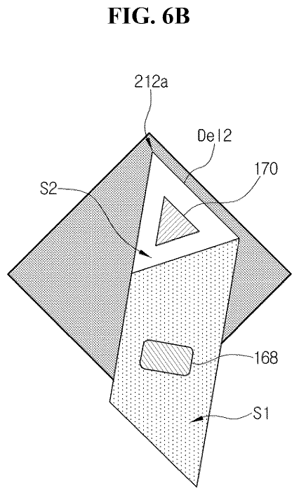

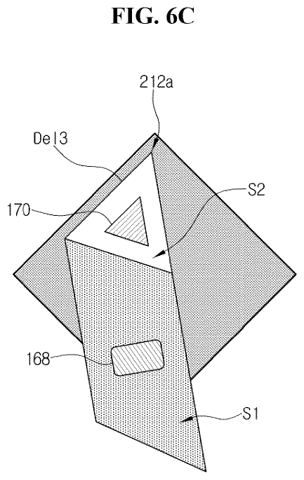

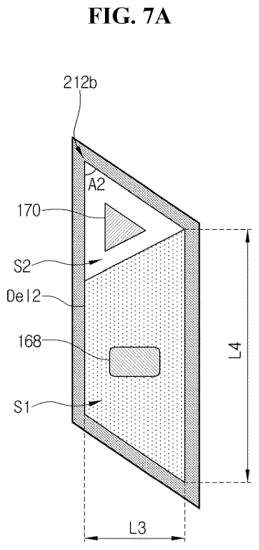

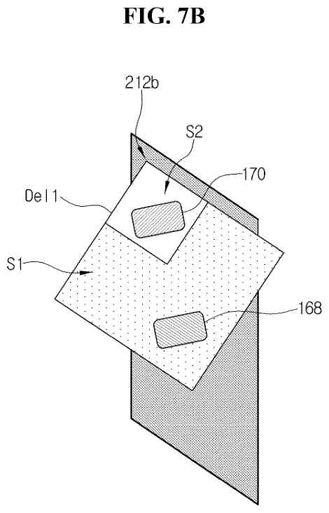

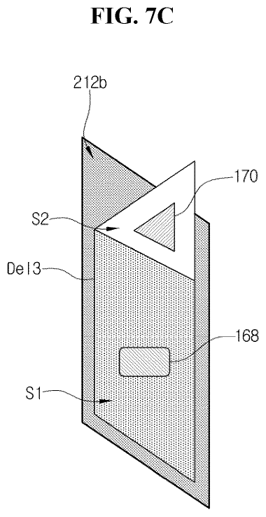

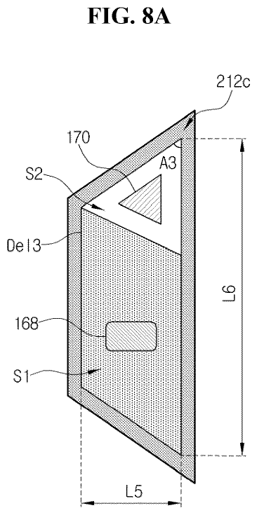

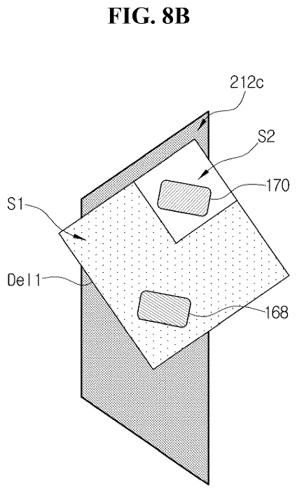

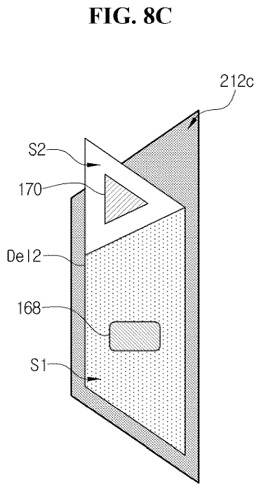

The plurality of LEDs Del include first, second and third LEDs Del1 (of FIG. 6A), Del2 (of FIG. 7A) and Del3 (of FIG. 8A) emitting first, second and third colored lights, respectively, and the plurality of assembly grooves 212 include first, second and third assembly grooves 212a (of FIG. 6A), 212b (of FIG. 7A) and 212c (of FIG. 8A) corresponding to the first, second and third LEDs Del1, Del2 and Del3, respectively.

For example, the first, second and third colored lights may correspond to red, green and blue, respectively.

When the first, second and third LEDs Del1, Del2 and Del3 are properly assembled to the first, second and third assembly grooves 212a, 212b and 212c, respectively, an electric force applied to the first, second and third LEDs Del1, Del2 and Del3 by the electric field of the first and second assembly electrodes 220 and 222 becomes greater than a magnetic force applied to the first, second and third LEDs Del1, Del2 and Del3 by the magnetic field of the magnetic rod 230 so that the first, second and third LEDs Del1, Del2 and Del3 cannot escape from and can be stably fixed to the first, second and third assembly grooves 212a, 212b and 212c, respectively.

When the first, second and third LEDs Del1, Del2 and Del3 are not properly assembled to the first, second and third assembly grooves 212a, 212b and 212c, respectively, the magnetic force applied to the first, second and third LEDs Del1, Del2 and Del3 by the magnetic field of the magnetic rod 230 becomes greater than the electric force applied to the first, second and third LEDs Del1, Del2 and Del3 by the electric field of the first and second assembly electrodes 220 and 222 so that the first, second and third LEDs Del1, Del2 and Del3 can escape from the first, second and third assembly grooves 212a, 212b and 212c, respectively. The first, second and third LEDs Del1, Del2 and Del3 having escaped from the first, second and third assembly grooves 212a, 212b and 212c may float in the fluid 234 till the first, second and third LEDs Del1, Del2 and Del3 are properly assembled to the first, second and third assembly grooves 212a, 212b and 212c, respectively.

When the plurality of LEDs Del are properly assembled to the plurality of assembly grooves 212 of the assembly substrate 210, the assembly substrate 210 is disposed on the adhesive layer 160 of the substrate 130 of the display panel 128, and the plurality of LEDs Del of the plurality of assembly grooves 212 are transferred and attached to the adhesive layer 160 of each subpixel SP1, SP2 and SP3.

In another embodiment, a transfer step may be omitted using the substrate 130 having the driving transistor Tdr as the assembly substrate 210.

Shapes of the plurality of assembly grooves 212 and the plurality of LEDs Del will be illustrated with reference to drawings.

FIG. 6A is a view showing a first assembly groove of an assembly substrate and a first light emitting diode for a fabrication of a display device according to a first embodiment of the present disclosure, FIG. 6B is a view showing a first assembly groove of an assembly substrate and a second light emitting diode for a fabrication of a display device according to a first embodiment of the present disclosure, and FIG. 6C is a view showing a first assembly groove of an assembly substrate and a third light emitting diode for a fabrication of a display device according to a first embodiment of the present disclosure. FIG. 7A is a view showing a second assembly groove of an assembly substrate and a second light emitting diode for a fabrication of a display device according to a first embodiment of the present disclosure, FIG. 7B is a view showing a second assembly groove of an assembly substrate and a first light emitting diode for a fabrication of a display device according to a first embodiment of the present disclosure, and FIG. 7C is a view showing a second assembly groove of an assembly substrate and a third light emitting diode for a fabrication of a display device according to a first embodiment of the present disclosure. FIG. 8A is a view showing a third assembly groove of an assembly substrate and a third light emitting diode for a fabrication of a display device according to a first embodiment of the present disclosure, FIG. 8B is a view showing a third assembly groove of an assembly substrate and a first light emitting diode for a fabrication of a display device according to a first embodiment of the present disclosure, and FIG. 8C is a view showing a third assembly groove of an assembly substrate and a second light emitting diode for a fabrication of a display device according to a first embodiment of the present disclosure.

In FIG. 6A, a first light emitting diode (LED) Del1 of the first subpixel SP1 of the display device 110 according to a first embodiment of the present disclosure has a square shape where one corner corresponding to the second electrode 170 has an angled shape of about 90 degrees (a shape where a first angle A1 between connected two sides is about 90 degrees), and a first assembly groove 212a of the assembly substrate 210 where the first LED Del1 is assembled has a square shape corresponding to the first LED Del1.

In another embodiment, the first LED Del1 may have one of a square shape where one corner corresponding to the first electrode 168 has an angled shape of about 90 degrees, a lozenge (diamond) shape where one corner corresponding to the first electrode 168 or the second electrode 170 has an angled shape greater than about 90 degrees and a lozenge shape where one corner corresponding to the first electrode 168 or the second electrode 170 has an angled shape smaller than about 90 degrees.

The first LED Del1 has a square shape having first and second lengths L1 and L2 along horizontal and vertical directions, respectively, and the first assembly groove 212a has a square shape greater than the first LED Del1.

For example, the first and second lengths L1 and L2 may be about 14 μm and about 14 μm, respectively, and the first assembly groove 212a may have a size of a horizontal length of about 18 μm and a vertical length of about 18 μm.

A top surface of the first LED Del1 includes a first surface S1 having the first electrode 168 over a step difference in a cross-sectional view and a second surface S2 having the second electrode 170 under the step difference in a cross-sectional view. The first surface S1 may have a chevron shape which is a square except for the second surface S2, and the second surface S2 may have a square shape.

As a result, the first LED Del1 is stably assembled to the first assembly groove 212a.

In FIG. 7A, a second light emitting diode (LED) Del2 of the second subpixel SP2 of the display device 110 according to a first embodiment of the present disclosure has a parallelogram shape where one corner corresponding to the second electrode 170 has an angled shape of about 45 degrees to about 55 degrees (a shape where a second angle A2 between connected two sides is about 45 degrees to about 55 degrees), and a second assembly groove 212b of the assembly substrate 210 where the second LED Del2 is assembled has a parallelogram shape corresponding to the second LED Del2.

When the second angle A2 is smaller than about 45 degrees, a distinguishability (exclusivity) between the second and third LEDs Del2 and Del3 decreases. When the second angle A2 is greater than about 55 degrees, a possibility of deterioration in a fabrication of the second LED Del2 increases.

In another embodiment, the second LED Del2 may have a parallelogram shape where one corner corresponding to the first electrode 168 has an angled shape of about 45 degrees to about 55 degrees.

The second LED Del2 has a parallelogram shape having third and fourth lengths L3 and L4 along horizontal and vertical directions, respectively, and the second assembly groove 212b has a parallelogram shape greater than the second LED Del2.

For example, the third and fourth lengths L3 and L4 may be about 10 μm and about 18 μm, respectively, and the second assembly groove 212b may have a size of a horizontal length of about 14 μm and a vertical length of about 22 μm.

A top surface of the second LED Del2 includes a first surface S1 having the first electrode 168 over a step difference in a cross-sectional view and a second surface S2 having the second electrode 170 under the step difference in a cross-sectional view. The first surface S1 may have an equilateral trapezoid shape, and the second surface S2 may have a triangle shape.

As a result, the second LED Del2 is stably assembled to the second assembly groove 212b.

In FIG. 8A, a third light emitting diode (LED) Del3 of the third subpixel SP3 of the display device 110 according to a first embodiment of the present disclosure has an equilateral trapezoid shape where one corner corresponding to the second electrode 170 has an angled shape of about 45 degrees to about 55 degrees (a shape where a third angle A3 between connected two sides is about 45 degrees to about 55 degrees), and a third assembly groove 212c of the assembly substrate 210 where the third LED Del3 is assembled has an equilateral trapezoid shape corresponding to the third LED Del3.

When the third angle A3 is smaller than about 45 degrees, a distinguishability (exclusivity) between the second and third LEDs Del2 and Del3 decreases. When the third angle A3 is greater than about 55 degrees, a possibility of deterioration in a fabrication of the third LED Del3 increases.

In another embodiment, the third LED Del3 may have an equilateral trapezoid shape where one corner corresponding to the first electrode 168 has an angled shape of about 45 degrees to about 55 degrees.

The one corner of the third LED Del3 of an angled shape is disposed opposite to the one corner of the second LED Del2 of an angled shape.

For example, a left-up corner may have an angled shape in the second LED Del2, and a right-up corner may have an angled shape in the third LED Del3.

The third LED Del3 has an equilateral trapezoid shape having fifth and sixth lengths L5 and L6 along horizontal and vertical directions, respectively, and the third assembly groove 212c has an equilateral trapezoid shape greater than the third LED Del3.

For example, the fifth and sixth lengths L5 and L6 may be about 10 μm and about 18 μm, respectively, and the third assembly groove 212c may have a size of a horizontal length of about 14 μm and a vertical length of about 22 μm.

A top surface of the third LED Del3 includes a first surface S1 having the first electrode 168 over a step difference in a cross-sectional view and a second surface S2 having the second electrode 170 under the step difference in a cross-sectional view. The first surface S1 may have a parallelogram shape, and the second surface S2 may have a triangle shape.

As a result, the third LED Del3 is stably assembled to the third assembly groove 212c.

In FIGS. 6B and 6C, even when one corner of each of the second and third LEDs Del2 and Del3 is inserted into the first assembly groove 212a to correspond to one corner of the first assembly groove 212a, at least one end portion of each of the second and third LEDs Del2 and Del3 is disposed beyond the first assembly groove 212a. As a result, each of the second and third LEDs Del2 and Del3 is not assembled to and easily escapes from the first assembly groove 212a.

In FIGS. 7B and 7C, even when one corner of each of the first and third LEDs Del1 and Del3 is inserted into the second assembly groove 212b to correspond to one corner of the second assembly groove 212b, at least one end portion of each of the first and third LEDs Del1 and Del3 is disposed beyond the second assembly groove 212b. As a result, each of the first and third LEDs Del1 and Del3 is not assembled to and easily escapes from the second assembly groove 212b.

In FIGS. 8B and 8C, even when one corner of each of the first and second LEDs Del1 and Del2 is inserted into the third assembly groove 212c to correspond to one corner of the third assembly groove 212c, at least one end portion of each of the first and second LEDs Del1 and Del2 is disposed beyond the third assembly groove 212c. As a result, each of the first and second LEDs Del1 and Del2 is not assembled to and easily escapes from the third assembly groove 212c.

In the display device 110 according to a first embodiment of the present disclosure, the first, second and third LEDs Del1, Del2 and Del3 are formed to have the corners of asymmetric angled shapes different from each other, and the first, second and third assembly grooves 212a, 212b and 212c are formed to have shapes corresponding to the first, second and third LEDs Del1, Del2 and Del3. As a result, an exclusivity between the first, second and third LEDs Del1, Del2 and Del3 is improved, and a mixture of colors due to a mis-assembly of the first, second and third LEDs Del1, Del2 and Del3 is prevented to obtain a relatively high resolution.

Although the first, second and third colors of the first, second and third LEDs Del1, Del2 and Del3 correspond to red, green and blue, respectively, in the first embodiment, the first, second and third colors may correspond to green, blue and red, respectively, to blue, red and green, respectively, or to colors different from each other in another embodiment.

The first, second and third LEDs Del1, Del2 and Del3 having different asymmetric angled shapes will be illustrated with reference to drawings.

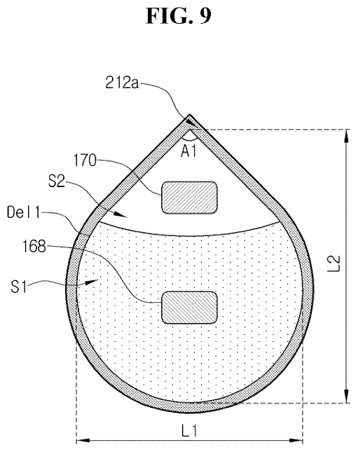

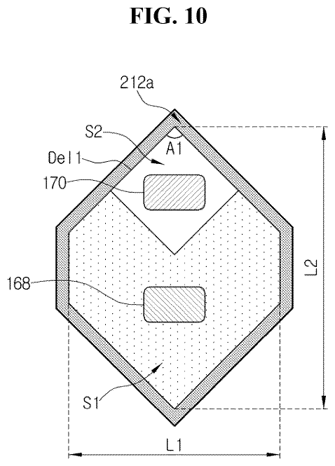

FIG. 9 is a view showing a first assembly groove of an assembly substrate and a first light emitting diode for a fabrication of a display device according to a second embodiment of the present disclosure.

In FIG. 9, a first light emitting diode (LED) Del1 of a first subpixel SP1 of a display device 110 according to a second embodiment of the present disclosure has a water drop shape where one corner corresponding to a second electrode 170 has an angled shape of about 90 degrees (a shape where a first angle A1 between connected two sides is about 90 degrees), and a first assembly groove 212a of an assembly substrate 210 where the first LED Del1 is assembled has a water drop shape corresponding to the first LED Del1.

In another embodiment, the first LED Del1 may have a water drop shape where one corner corresponding to a first electrode 168 has an angled shape of about 90 degrees.

The first LED Del1 has a water drop shape having first and second lengths L1 and L2 along horizontal and vertical directions, respectively, and the first assembly groove 212a has a water drop shape greater than the first LED Del1.

For example, the first and second lengths L1 and L2 may be about 13 μm and about 15 μm, respectively, and the first assembly groove 212a may have a size of a horizontal length of about 17 μm and a vertical length of about 19 μm.

A top surface of the first LED Del1 includes a first surface S1 having the first electrode 168 over a step difference in a cross-sectional view and a second surface S2 having the second electrode 170 under the step difference in a cross-sectional view. The first surface S1 may have a waning moon shape which is a water drop except for the second surface S2, and the second surface S2 may have a fan shape.

As a result, the first LED Del1 is stably assembled to the first assembly groove 212a.

FIG. 10 is a view showing a first assembly groove of an assembly substrate and a first light emitting diode for a fabrication of a display device according to a third embodiment of the present disclosure.

In FIG. 10, a first light emitting diode (LED) Del1 of a first subpixel SP1 of a display device 110 according to a third embodiment of the present disclosure has a hexagon shape where one corner corresponding to a second electrode 170 has an angled shape of about 90 degrees (a shape where a first angle A1 between connected two sides is about 90 degrees), and a first assembly groove 212a of an assembly substrate 210 where the first LED Del1 is assembled has a hexagon shape corresponding to the first LED Del1.

In another embodiment, the first LED Del1 may have a hexagon shape where one corner corresponding to a first electrode 168 has an angled shape of about 90 degrees.

The first LED Del1 has a hexagon shape having first and second lengths L1 and L2 along horizontal and vertical directions, respectively, and the first assembly groove 212a has a hexagon shape greater than the first LED Del1.

For example, the first and second lengths L1 and L2 may be about 13 μm and about 15 μm, respectively, and the first assembly groove 212a may have a size of a horizontal length of about 17 μm and a vertical length of about 19 μm.

A top surface of the first LED Del1 includes a first surface S1 having the first electrode 168 over a step difference in a cross-sectional view and a second surface S2 having the second electrode 170 under the step difference in a cross-sectional view. The first surface S1 may have a chamfered chevron shape which is a hexagon except for the second surface S2, and the second surface S2 may have a square shape.

As a result, the first LED Del1 is stably assembled to the first assembly groove 212a.

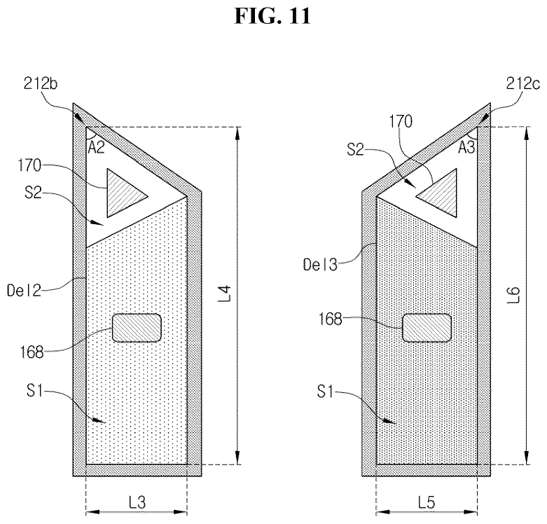

FIG. 11 is a view showing second and third assembly grooves of an assembly substrate and second and third light emitting diodes for a fabrication of a display device according to a fourth embodiment of the present disclosure.

In FIG. 11, a second light emitting diode (LED) Del2 of a second subpixel SP2 of a display device 110 according to a fourth embodiment of the present disclosure has a trapezoid shape where one corner corresponding to a second electrode 170 has an angled shape of about 45 degrees to about 55 degrees (a shape where a second angle A2 between connected two sides is about 45 degrees to about 55 degrees), and a second assembly groove 212b of an assembly substrate 210 where the second LED Del2 is assembled has a trapezoid shape corresponding to the second LED Del2.

When the second angle A2 is smaller than about 45 degrees, a distinguishability (exclusivity) between the second and third LEDs Del2 and Del3 decreases. When the second angle A2 is greater than about 55 degrees, a possibility of deterioration in a fabrication of the second LED Del2 increases.

In another embodiment, the second LED Del2 may have a trapezoid shape where one corner corresponding to a first electrode 168 has an angled shape of about 45 degrees to about 55 degrees.

The one corner of the third LED Del3 of an angled shape is disposed opposite to the one corner of the second LED Del2 of an angled shape.

For example, a left-up corner may have an angled shape in the second LED Del2, and a right-up corner may have an angled shape in the third LED Del3.

The second LED Del2 has a trapezoid shape having third and fourth lengths L3 and L4 along horizontal and vertical directions, respectively, where a portion opposite to the one corner is flat, and the second assembly groove 212b has a trapezoid shape greater than the second LED Del2.

For example, the third and fourth lengths L3 and L4 may be about 10 μm and about 21 μm, respectively, and the second assembly groove 212b may have a size of a horizontal length of about 14 μm and a vertical length of about 25 μm.

A top surface of the second LED Del2 includes a first surface S1 having the first electrode 168 over a step difference in a cross-sectional view and a second surface S2 having the second electrode 170 under the step difference in a cross-sectional view. The first surface S1 may have a trapezoid shape where a portion opposite to the one corner is flat, and the second surface S2 may have a triangle shape.

As a result, the second LED Del2 is stably assembled to the second assembly groove 212b.

A third light emitting diode (LED) Del3 of a third subpixel SP3 of a display device 110 according to a fourth embodiment of the present disclosure has a trapezoid shape where one corner corresponding to a second electrode 170 has an angled shape of about 45 degrees to about 55 degrees (a shape where a third angle A3 between connected two sides is about 45 degrees to about 55 degrees), and a third assembly groove 212c of an assembly substrate 210 where the third LED Del3 is assembled has a trapezoid shape corresponding to the third LED Del3.

When the third angle A3 is smaller than about 45 degrees, a distinguishability (exclusivity) between the second and third LEDs Del2 and Del3 decreases. When the third angle A3 is greater than about 55 degrees, a possibility of deterioration in a fabrication of the third LED Del3 increases.

In another embodiment, the third LED Del3 may have a trapezoid shape where one corner corresponding to a first electrode 168 has an angled shape of about 45 degrees to about 55 degrees.

The third LED Del3 has a trapezoid shape having fifth and sixth lengths L5 and L6 along horizontal and vertical directions, respectively, where a portion opposite to the one corner is flat, and the third assembly groove 212c has a trapezoid shape greater than the third LED Del3.

For example, the fifth and sixth lengths L5 and L6 may be about 10 μm and about 21 μm, respectively, and the third assembly groove 212c may have a size of a horizontal length of about 14 μm and a vertical length of about 25 μm.

A top surface of the third LED Del3 includes a first surface S1 having the first electrode 168 over a step difference in a cross-sectional view and a second surface S2 having the second electrode 170 under the step difference in a cross-sectional view. The first surface S1 may have a trapezoid shape where a portion opposite to the one corner is flat, and the second surface S2 may have a triangle shape.

As a result, the third LED Del3 is stably assembled to the third assembly groove 212c.

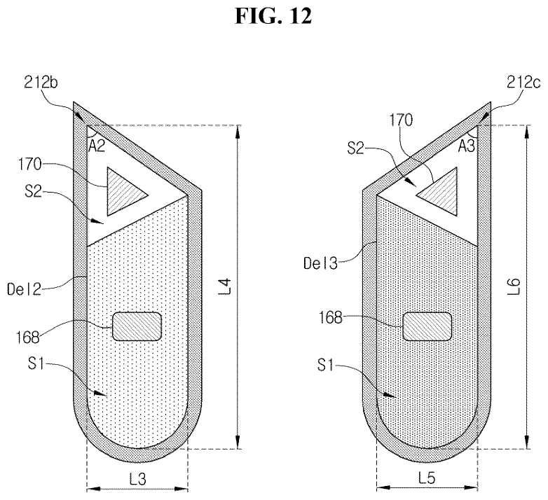

FIG. 12 is a view showing second and third assembly grooves of an assembly substrate and second and third light emitting diodes for a fabrication of a display device according to a fifth embodiment of the present disclosure.

In FIG. 12, a second light emitting diode (LED) Del2 of a second subpixel SP2 of a display device 110 according to a fifth embodiment of the present disclosure has a trapezoid shape including a round portion where one corner corresponding to a second electrode 170 has an angled shape of about 45 degrees to about 55 degrees (a shape where a second angle A2 between connected two sides is about 45 degrees to about 55 degrees), and a second assembly groove 212b of an assembly substrate 210 where the second LED Del2 is assembled has a trapezoid shape corresponding to the second LED Del2.

When the second angle A2 is smaller than about 45 degrees, a distinguishability (exclusivity) between the second and third LEDs Del2 and Del3 decreases. When the second angle A2 is greater than about 55 degrees, a possibility of deterioration in a fabrication of the second LED Del2 increases.

In another embodiment, the second LED Del2 may have a trapezoid shape where one corner corresponding to a first electrode 168 has an angled shape of about 45 degrees to about 55 degrees.

The one corner of the third LED Del3 of an angled shape is disposed opposite to the one corner of the second LED Del2 of an angled shape.

For example, a left-up corner may have an angled shape in the second LED Del2, and a right-up corner may have an angled shape in the third LED Del3.

The second LED Del2 has a trapezoid shape having third and fourth lengths L3 and L4 along horizontal and vertical directions, respectively, where a portion opposite to the one corner is round, and the second assembly groove 212b has a trapezoid shape greater than the second LED Del2.

For example, the third and fourth lengths L3 and L4 may be about 10 μm and about 21 μm, respectively, and the second assembly groove 212b may have a size of a horizontal length of about 14 μm and a vertical length of about 25 μm.

A top surface of the second LED Del2 includes a first surface S1 having the first electrode 168 over a step difference in a cross-sectional view and a second surface S2 having the second electrode 170 under the step difference in a cross-sectional view. The first surface S1 may have a trapezoid shape where a portion opposite to the one corner is round, and the second surface S2 may have a triangle shape.

As a result, the second LED Del2 is stably assembled to the second assembly groove 212b.

A third light emitting diode (LED) Del3 of a third subpixel SP3 of a display device 110 according to a fifth embodiment of the present disclosure has a trapezoid shape including a round portion where one corner corresponding to a second electrode 170 has an angled shape of about 45 degrees to about 55 degrees (a shape where a third angle A3 between connected two sides is about 45 degrees to about 55 degrees), and a third assembly groove 212c of an assembly substrate 210 where the third LED Del3 is assembled has a trapezoid shape corresponding to the third LED Del3.

When the third angle A3 is smaller than about 45 degrees, a distinguishability (exclusivity) between the second and third LEDs Del2 and Del3 decreases. When the third angle A3 is greater than about 55 degrees, a possibility of deterioration in a fabrication of the third LED Del3 increases.

In another embodiment, the third LED Del3 may have a trapezoid shape where one corner corresponding to a first electrode 168 has an angled shape of about 45 degrees to about 55 degrees.

The third LED Del3 has a trapezoid shape having fifth and sixth lengths L5 and L6 along horizontal and vertical directions, respectively, where a portion opposite to the one corner is round, and the third assembly groove 212c has a trapezoid shape greater than the third LED Del3.

For example, the fifth and sixth lengths L5 and L6 may be about 10 μm and about 21 μm, respectively, and the third assembly groove 212c may have a size of a horizontal length of about 14 μm and a vertical length of about 25 μm.

A top surface of the third LED Del3 includes a first surface S1 having the first electrode 168 over a step difference in a cross-sectional view and a second surface S2 having the second electrode 170 under the step difference in a cross-sectional view. The first surface S1 may have a trapezoid shape where a portion opposite to the one corner is round, and the second surface S2 may have a triangle shape.

As a result, the third LED Del3 is stably assembled to the third assembly groove 212c.

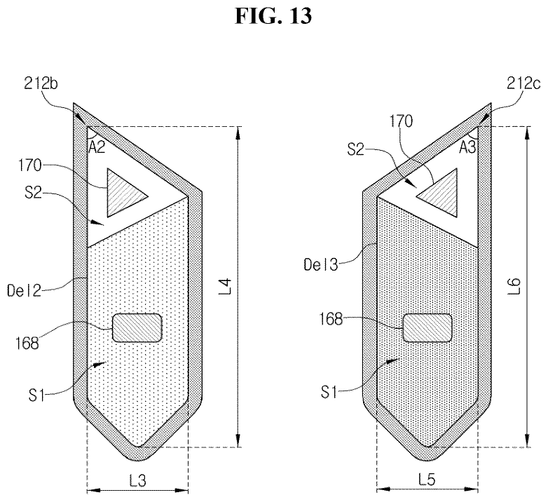

FIG. 13 is a view showing second and third assembly grooves of an assembly substrate and second and third light emitting diodes for a fabrication of a display device according to a sixth embodiment of the present disclosure.

In FIG. 13, a second light emitting diode (LED) Del2 of a second subpixel SP2 of a display device 110 according to a sixth embodiment of the present disclosure has a pentagon shape including a round portion where one corner corresponding to a second electrode 170 has an angled shape of about 45 degrees to about 55 degrees (a shape where a second angle A2 between connected two sides is about 45 degrees to about 55 degrees), and a second assembly groove 212b of an assembly substrate 210 where the second LED Del2 is assembled has a pentagon shape corresponding to the second LED Del2.

When the second angle A2 is smaller than about 45 degrees, a distinguishability (exclusivity) between the second and third LEDs Del2 and Del3 decreases. When the second angle A2 is greater than about 55 degrees, a possibility of deterioration in a fabrication of the second LED Del2 increases.

In another embodiment, the second LED Del2 may have a pentagon shape where one corner corresponding to a first electrode 168 has an angled shape of about 45 degrees to about 55 degrees.

The one corner of the third LED Del3 of an angled shape is disposed opposite to the one corner of the second LED Del2 of an angled shape.

For example, a left-up corner may have an angled shape in the second LED Del2, and a right-up corner may have an angled shape in the third LED Del3.

The second LED Del2 has a pentagon shape having third and fourth lengths L3 and L4 along horizontal and vertical directions, respectively, where a portion opposite to the one corner is round, and the second assembly groove 212b has a pentagon shape greater than the second LED Del2.

For example, the third and fourth lengths L3 and L4 may be about 10 μm and about 21 μm, respectively, and the second assembly groove 212b may have a size of a horizontal length of about 14 μm and a vertical length of about 25 μm.

A top surface of the second LED Del2 includes a first surface S1 having the first electrode 168 over a step difference in a cross-sectional view and a second surface S2 having the second electrode 170 under the step difference in a cross-sectional view. The first surface S1 may have a pentagon shape where a portion opposite to the one corner is round, and the second surface S2 may have a triangle shape.

As a result, the second LED Del2 is stably assembled to the second assembly groove 212b.

A third light emitting diode (LED) Del3 of a third subpixel SP3 of a display device 110 according to a sixth embodiment of the present disclosure has a pentagon shape including a round portion where one corner corresponding to a second electrode 170 has an angled shape of about 45 degrees to about 55 degrees (a shape where a third angle A3 between connected two sides is about 45 degrees to about 55 degrees), and a third assembly groove 212c of an assembly substrate 210 where the third LED Del3 is assembled has a pentagon shape corresponding to the third LED Del3.

When the third angle A3 is smaller than about 45 degrees, a distinguishability (exclusivity) between the second and third LEDs Del2 and Del3 decreases. When the third angle A3 is greater than about 55 degrees, a possibility of deterioration in a fabrication of the third LED Del3 increases.

In another embodiment, the third LED Del3 may have a pentagon shape where one corner corresponding to a first electrode 168 has an angled shape of about 45 degrees to about 55 degrees.

The third LED Del3 has a pentagon shape having fifth and sixth lengths L5 and L6 along horizontal and vertical directions, respectively, where a portion opposite to the one corner is round, and the third assembly groove 212c has a pentagon shape greater than the third LED Del3.

For example, the fifth and sixth lengths L5 and L6 may be about 10 μm and about 21 μm, respectively, and the third assembly groove 212c may have a size of a horizontal length of about 14 μm and a vertical length of about 25 μm.

A top surface of the third LED Del3 includes a first surface S1 having the first electrode 168 over a step difference in a cross-sectional view and a second surface S2 having the second electrode 170 under the step difference in a cross-sectional view. The first surface S1 may have a pentagon shape where a portion opposite to the one corner is round, and the second surface S2 may have a triangle shape.

As a result, the third LED Del3 is stably assembled to the third assembly groove 212c.

In the display device 110 according to second to sixth embodiments of the present disclosure, the first, second and third LEDs Del1, Del2 and Del3 are formed to have the corners of asymmetric angled shapes different from each other, and the first, second and third assembly grooves 212a, 212b and 212c are formed to have shapes corresponding to the first, second and third LEDs Del1, Del2 and Del3. As a result, an exclusivity between the first, second and third LEDs Del1, Del2 and Del3 is improved, and a mixture of colors due to a mis-assembly of the first, second and third LEDs Del1, Del2 and Del3 is prevented to obtain a relatively high resolution.

Consequently, a color mixture is prevented and a fabrication process is optimized by forming the light emitting diodes as an asymmetric angled shape. Further, a simultaneous assembly technology is applied to a relatively high resolution by forming the red, green and blue light emitting diodes as different asymmetric angled shapes.

Further embodiments also include a method that provides an innovative approach to fabricating high-precision display devices by leveraging distinct asymmetric angled shapes for red, green, and blue LEDs. By designing corresponding assembly grooves that geometrically complement each LED type, the process enables accurate placement of each LED into its designated position. This structural alignment is achieved not through manual intervention but by applying a directed force—such as a dielectric phoretic force, electric force, or magnetic force—which guides the LEDs into their respective grooves. This method enhances manufacturing efficiency and precision, particularly important in high-resolution micro-LED displays.

Furthermore, the use of force-driven assembly introduces a self-correcting mechanism. Due to the asymmetric shape of the LEDs and matching grooves, any LED that is misaligned or placed incorrectly is naturally dislodged or rejected by the force, ensuring only correctly oriented LEDs remain in place. This self-alignment property significantly reduces assembly errors and increases yield rates.

It will be apparent to those skilled in the art that various modifications and variation may be made in the present disclosure without departing from the scope of the disclosure. Thus, it is intended that the present disclosure cover the modifications and variations of this disclosure provided they come within the scope of the appended claims and their equivalents.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel having a display area and a non-display area adjacent to the display area;
a plurality of gate lines and a plurality of data lines in the display area, the plurality of gate lines and the plurality of data lines crossing each other;
first, second and third subpixels;
a driving transistor in each of the first, second and third subpixels and connected to the plurality of gate lines and the plurality of data lines; and
first, second and third light emitting diodes in the first, second and third subpixels, respectively, and connected to the driving transistor, one corner of the first light emitting diode, one corner of the second light emitting diode and one corner of the third light emitting diode having asymmetric angled shapes different from each other.

2. The display device of claim 1, wherein the first light emitting diode has one of a square shape, a lozenge shape, a water drop shape, and a hexagon shape.

3. The display device of claim 1, wherein the one corner of an angled shape of the second light emitting diode and the one corner of an angled shape of the third light emitting diode are disposed opposite to each other.

4. The display device of claim 3, wherein the second light emitting diode has a parallelogram shape, and the third light emitting diode has an equilateral trapezoid shape.

5. The display device of claim 3, wherein the second light emitting diode has a trapezoid shape, and the third light emitting diode has a trapezoid shape.

6. The display device of claim 3, wherein the second light emitting diode has a trapezoid shape including a round portion, and the third light emitting diode has a trapezoid shape including a round portion.

7. The display device of claim 3, wherein the second light emitting diode has a pentagon shape including a round portion, and the third light emitting diode has a pentagon shape including a round portion.

8. The display device of claim 1, wherein a first angle between two sides of the one corner of the first light emitting diode is 90 degrees,
wherein a second angle between two sides of the one corner of the second light emitting diode is 45 degrees to 55 degrees, and
wherein a third angle between two sides of the one corner of the third light emitting diode is 45 degrees to 55 degrees.

9. The display device of claim 1, wherein each of the first, second and third light emitting diodes comprises:
a first semiconductor layer;
an active layer on a first portion of the first semiconductor layer;
a second semiconductor layer on the active layer;
a first electrode on the second semiconductor layer; and
a second electrode on a second portion of the first semiconductor layer.

10. The display device of claim 9, wherein a top surface of each of the first, second and third light emitting diodes includes a first surface having the first electrode over a step difference in a cross-sectional view and a second surface having the second electrode over the step difference in a cross-sectional view.

11. The display device of claim 10, wherein the first surface of the first light emitting diode has a chevron shape, and the second surface of the first light emitting diode has a square shape,
wherein the first surface of the second light emitting diode has an equilateral trapezoid shape, and the second surface of the second light emitting diode has a triangle shape, and
wherein the first surface of the third light emitting diode has a parallelogram shape, and the second surface of the third light emitting diode has a triangle shape.

12. The display device of claim 10, wherein the first surface of the first light emitting diode has a waning moon shape, and the second surface of the first light emitting diode has a fan shape,
wherein the first surface of the second light emitting diode has an equilateral trapezoid shape, and the second surface of the second light emitting diode has a triangle shape, and
wherein the first surface of the third light emitting diode has a parallelogram shape, and the second surface of the third light emitting diode has a triangle shape.

13. The display device of claim 10, wherein the first surface of the first light emitting diode has a chamfered chevron shape, and the second surface of the first light emitting diode has a square shape,
wherein the first surface of the second light emitting diode has an equilateral trapezoid shape, and the second surface of the second light emitting diode has a triangle shape, and
wherein the first surface of the third light emitting diode has a parallelogram shape, and the second surface of the third light emitting diode has a triangle shape.

14. The display device of claim 10, wherein the first surface of the first light emitting diode has a chevron shape, and the second surface of the first light emitting diode has a square shape,
wherein the first surface of the second light emitting diode has a trapezoid shape, and the second surface of the second light emitting diode has a triangle shape, and
wherein the first surface of the third light emitting diode has a trapezoid shape, and the second surface of the third light emitting diode has a triangle shape.

15. The display device of claim 10, wherein the first surface of the first light emitting diode has a chevron shape, and the second surface of the first light emitting diode has a square shape,
wherein the first surface of the second light emitting diode has a trapezoid shape having a round portion, and the second surface of the second light emitting diode has a triangle shape, and
wherein the first surface of the third light emitting diode has a trapezoid shape having a round portion, and the second surface of the third light emitting diode has a triangle shape.

16. The display device of claim 10, wherein the first surface of the first light emitting diode has a chevron shape, and the second surface of the first light emitting diode has a square shape,
wherein the first surface of the second light emitting diode has a pentagon shape having a round portion, and the second surface of the second light emitting diode has a triangle shape, and
wherein the first surface of the third light emitting diode has a pentagon shape having a round portion, and the second surface of the third light emitting diode has a triangle shape.

17. The display device of claim 1, wherein the first light emitting diode has a first length of 14 μm along a horizontal direction and a second length of 14 μm along a vertical direction,
wherein the second light emitting diode has a third length of 10 μm along the horizontal direction and a fourth length of 18 μm along the vertical direction, and
wherein third light emitting diode has a fifth length of 10 μm along the horizontal direction and a sixth length of 18 μm along the vertical direction.
